(19) United States
(12) Patent Application Publication
(10) Pub. No.: US 2023/0036227 A1
(43) Pub. Date: Feb. 2, 2023

(54) METHOD OF MANUFACTURING PHOTOELECTRIC CONVERSION DEVICE, AND PHOTOELECTRIC CONVERSION DEVICE

(71) Applicant: SONY SEMICONDUCTOR SOLUTIONS CORPORATION, KANAGAWA (JP)

(72) Inventors: TAKUYA KUROTORI, TOKYO (JP); YOSHINORI KODAMA, KANAGAWA (JP); YUKI MIYANAMI, KANAGAWA (JP)

(21) Appl. No.: 17/758,579

(22) PCT Filed: Jan. 7, 2021
(86) PCT No.: PCT/JP2021/000347

§ 371 Date: Jul. 11, 2022

(30) Foreign Application Priority Data
Jan. 20, 2020 (JP) 2020-007097

(51) Int. Cl. H01L 27/146

(52) U.S. Cl. CPC H01L 27/14685; H01L 27/14645; H01L 27/14621; H01L 27/14623; H01L 27/14627; H01L 27/1463

(57) ABSTRACT

A method of manufacturing a photoelectric conversion device includes: forming a photoelectric conversion structure in which a first semiconductor layer of a first electrical conductivity type is provided on a non-light-receiving surface, on side opposite to a light-receiving surface, of a light-absorbing layer including a compound semiconductor; forming an opening by etching at least a portion of the photoelectric conversion structure, the opening that separates the photoelectric conversion structure for each pixel; and forming a pixel separator of a second electrical conductivity type on the light-absorbing layer exposed in the opening, the pixel separator extending in a thickness direction of the light-absorbing layer.

### TECHNICAL FIELD

The present disclosure relates to a method of manufacturing a photoelectric conversion device, and a photoelectric conversion device.

### BACKGROUND ART

In recent years, a sensor having sensitivity to an infrared region (so-called infrared sensor) has been practically used. For example, the infrared sensor is able to photoelectrically convert infrared rays by photoelectric conversion elements using a III-V group compound semiconductor such as InGaAs (indium gallium arsenide) (see PTL 1, for example).

In such an infrared sensor, the photoelectric conversion elements that photoelectrically convert infrared rays are two-dimensionally arranged for respective pixels, and signal electric charges are read pixel by pixel from the photoelectric conversion elements.

### CITATION LIST

### Patent Literature

PTL 1: International Publication No. WO2018/212175

### SUMMARY OF THE INVENTION

In such photoelectric conversion elements provided in an infrared sensor, it is desired to suppress crosstalk between adjacent pixels by suppressing movement of signal electric charges between the adjacent pixels.

It is therefore desirable to provide a method of manufacturing a photoelectric conversion device, and a photoelectric conversion device that make it possible to suppress crosstalk between adjacent pixels.

A method of manufacturing a photoelectric conversion device according to an embodiment of the present disclosure includes: forming a photoelectric conversion structure in which a first semiconductor layer of a first electrical conductivity type is provided on a non-light-receiving surface, on side opposite to a light-receiving surface, of a light-absorbing layer including a compound semiconductor; forming an opening by etching at least a portion of the photoelectric conversion structure, the opening that separates the photoelectric conversion structure for each pixel; and forming a pixel separator of a second electrical conductivity type on the light-absorbing layer exposed in the opening, the pixel separator extending in a thickness direction of the light-absorbing layer.

In addition, a photoelectric conversion device according to an embodiment of the present disclosure includes: a photoelectric conversion structure including a light-absorbing layer and a first semiconductor layer of a first electrical conductivity type, the light-absorbing layer including a compound semiconductor, and the first semiconductor layer provided on a non-light-receiving surface, on side opposite to a light-receiving surface, of the light-absorbing layer; an opening that is provided to penetrate through at least a portion of the photoelectric conversion structure, and separates the photoelectric conversion structure for each pixel; and a pixel separator of a second electrical conductivity type that is provided on the light-absorbing layer exposed in the opening, and extends in a thickness direction of the light-absorbing layer.

According to the method of manufacturing the photoelectric conversion device, and the photoelectric conversion device according to the embodiments of the present disclosure, there are provided the photoelectric conversion structure that includes the light-absorbing layer including the compound semiconductor, and the first semiconductor layer of the first electrical conductivity type provided on the non-light-receiving surface, on side opposite to the light-receiving surface, of the light-absorbing layer, the opening that is provided to penetrate through at least a portion of the photoelectric conversion structure and separates the photoelectric conversion structure for each pixel, and the pixel separator of the second electrical conductivity type that is provided on the light-absorbing layer exposed in the opening, and extends in the thickness direction of the light-absorbing layer. Accordingly, for example, it is possible to expand a potential barrier by the pixel separator to a deeper region of the light-absorbing layer, which makes it possible for the photoelectric conversion device to more firmly suppress movement of signal electric charges between pixels.

### BRIEF DESCRIPTION OF DRAWINGS

FIG. 1 is a vertical cross-sectional view of an example of a cross-sectional configuration of a photoelectric conversion device according to a first embodiment of the present disclosure.

FIG. 2A is a vertical cross-sectional view that describes each of processes of a method of manufacturing the photoelectric conversion device according to the same embodiment.

FIG. 2B is a vertical cross-sectional view that describes each of the processes of the method of manufacturing the photoelectric conversion device according to the same embodiment.

FIG. 2C is a vertical cross-sectional view that describes each of the processes of the method of manufacturing the photoelectric conversion device according to the same embodiment.

FIG. 2D is a vertical cross-sectional view that describes each of the processes of the method of manufacturing the photoelectric conversion device according to the same embodiment.

FIG. 3 is a vertical cross-sectional view of an example of a cross-sectional configuration of a photoelectric conversion device according to a modification example of the same embodiment.

FIG. 4 is a vertical cross-sectional view of another example of the cross-sectional configuration of the photoelectric conversion device according to the modification example of the same embodiment.

FIG. 5 is a vertical cross-sectional view of an example of a cross-sectional configuration of a photoelectric conversion device according to a second embodiment of the present disclosure.

FIG. 6A is a vertical cross-sectional view that describes each of processes of a method of manufacturing the photoelectric conversion device according to the same embodiment.

FIG. 6B is a vertical cross-sectional view that describes each of the processes of the method of manufacturing the photoelectric conversion device according to the same embodiment.

FIG. 6C is a vertical cross-sectional view that describes each of the processes of the method of manufacturing the photoelectric conversion device according to the same embodiment.

FIG. 6D is a vertical cross-sectional view that describes each of the processes of the method of manufacturing the photoelectric conversion device according to the same embodiment.

FIG. 6E is a vertical cross-sectional view that describes each of the processes of the method of manufacturing the photoelectric conversion device according to the same embodiment.

FIG. 7 is a vertical cross-sectional view of an example of a cross-sectional configuration of a photoelectric conversion device according to a first modification example of the same embodiment.

FIG. 8 is a vertical cross-sectional view of an example of a cross-sectional configuration of a photoelectric conversion device according to a second modification example of the same embodiment.

FIG. 9 is a vertical cross-sectional view of an example of a cross-sectional configuration of a photoelectric conversion device according to a third embodiment of the present disclosure.

FIG. 10A is a vertical cross-sectional view that describes, step by step, formation of a pixel separator in the photoelectric conversion device according to the same embodiment.

FIG. 10B is a vertical cross-sectional view that describes, step by step, formation of the pixel separator in the photoelectric conversion device according to the same embodiment.

FIG. 10C is a vertical cross-sectional view that describes, step by step, formation of the pixel separator in the photoelectric conversion device according to the same embodiment.

FIG. 11 is a block diagram illustrating an example of a schematic configuration of an imaging system including a light-receiving device that includes a photoelectric conversion device according to an embodiment of the present disclosure.

FIG. 12 is a flowchart diagram illustrating a flow of an imaging operation in the imaging system.

FIG. 13 is a block diagram depicting an example of schematic configuration of a vehicle control system.

FIG. 14 is a diagram of assistance in explaining an example of installation positions of an outside-vehicle information detecting section and an imaging section.

FIG. 15 is a view depicting an example of a schematic configuration of an endoscopic surgery system.

FIG. 16 is a block diagram depicting an example of a functional configuration of a camera head and a camera control unit (CCU).

### MODES FOR CARRYING OUT THE INVENTION

In the following, some embodiments of the present disclosure are described in detail with reference to the drawings. The following description is given of specific examples of the present disclosure, and the present disclosure is not limited to the following embodiments. Moreover, the present disclosure is not limited to positions, dimensions, dimension ratios, and the like of respective components illustrated in the respective drawings.

It is to be noted that description is given in the following order.
1. First Embodiment
   1.1. Configuration Example
   1.2. Manufacturing Method Example
   1.3. Modification Example
2. Second Embodiment
   2.1. Configuration Example
   2.2. Manufacturing Method Example
   2.3. Modification Examples
3. Third Embodiment
   3.1. Configuration Example
   3.2. Manufacturing Method Example
4. Application Examples

### 1. FIRST EMBODIMENT

### 1.1. Configuration Example

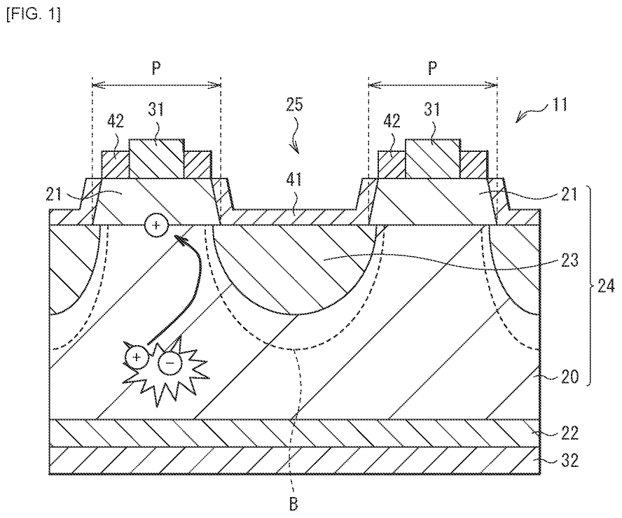

First, description is given of a configuration example of a photoelectric conversion device according to a first embodiment of the present disclosure with reference to FIG. 1. FIG. 1 is a vertical cross-sectional view of an example of a cross-sectional configuration of a photoelectric conversion device 11 according to the present embodiment.

As illustrated in FIG. 1, the photoelectric conversion device 11 includes, for example, a light-absorbing layer 20, a pixel separator 23, a first semiconductor layer 21, a first electrode 31, a second semiconductor layer 22, a second electrode 32, an insulating layer 41, and a protective layer 42. In the present embodiment, the light-absorbing layer 20 and the first semiconductor layer 21 that is stacked on one main surface (that is, a non-light-receiving surface) of the light-absorbing layer 20 are also collectively referred to as a photoelectric conversion structure 24.

The photoelectric conversion device 11 is able to photoelectrically convert, for example, light of a wavelength ranging from a visible light region (e.g., 380 nm or greater and less than 780 nm) to a near-infrared region (e.g., 780 nm or greater and less than 2400 nm). In addition, in the photoelectric conversion device 11, a pixel P is provided for each first semiconductor layer 21 and each first electrode 31 that are provided separately from each other, and a signal electric charge is read for each pixel P from the first electrode 31.

The light-absorbing layer 20 is a layer that absorbs light of a predetermined wavelength to generate signal electric charges. The light-absorbing layer 20 includes, for example, a compound semiconductor of a second electrical conductivity type (e.g., n-type), and is provided over a plurality of pixels P two-dimensionally arranged.

Specifically, the light-absorbing layer 20 may include an n-type III-V group compound semiconductor including one or more of In, Ga, Al, As, P, Sb, or N. Specific examples of the III-V group compound semiconductor include InGaAs, InGaAsP, InAsSb, InGaP, GaAsSb, InAlAs, and the like. For example, the light-absorbing layer 20 may include InGaAs including Si, S, Sn, As, P, Ge, C, or the like as an n--type impurity atom. The concentration of the n-type impurity atom in the light-absorbing layer 20 may be, for example, 1×10¹⁴ cm⁻³ to 1×10¹⁷ cm⁻³. The light-absorbing layer 20 may have, for example, a thickness of 100 nm to 10000 nm.

The first semiconductor layer 21 is provided for each pixel P separately by an opening 25 on one main surface (that is, a non-light-receiving surface) of the light-absorbing layer 20, for example. The first semiconductor layer 21 is sandwiched between the light-absorbing layer 20 and the first electrode 31, and is a layer in which a signal electric charge to be read from the light-absorbing layer 20 to the first electrode 31 is moved. The first semiconductor layer 21 may include a compound semiconductor of a first electrical conductivity type (e.g., p-type). The first semiconductor layer 21 may include, for example, p-type InP having a larger band gap than that of the compound semiconductor included in the light-absorbing layer 20. The first semiconductor layer 21 may include, for example, Zn, Ng, Be, or the like as a p-type impurity atom.

In the photoelectric conversion device 11 according to the present embodiment, the opening 25 is provided to penetrate through the first semiconductor layer 21 of the photoelectric conversion structure 24 including the first semiconductor layer 21 and the light-absorbing layer 20 and thus expose the light-absorbing layer 20. For example, the opening 25 may be formed by etching the first semiconductor layer 21, and may expose a flat surface of the light-absorbing layer 20 on a bottom surface of the opening 25.

The pixel separator 23 is a region of the second electrical conductivity type (e.g., n-type), and is provided on the light-absorbing layer 20 exposed in the opening 25 to extend in a thickness direction of the light-absorbing layer 20. Specifically, the pixel separator 23 may be provided to expand to a region of the light-absorbing layer 20 that is deeper on side of a middle portion of the opening 25 than on side of an end of the opening 25. For example, the pixel separator 23 may be provided on the light-absorbing layer 20 to expand semicircularly from the middle portion of the opening 25 as a center.

In the present embodiment, the pixel separator 23 is formed by plasma doping of the light-absorbing layer 20 with an impurity atom of the second electrical conductivity type (e.g., n-type). For this reason, the density of the n-type impurity atom in the pixel separator 23 is higher than the density of the n-type impurity atom in the light-absorbing layer 20. The pixel separator 23 is able to induce electric charges to a region below the first semiconductor layer 21 surrounded by the pixel separator 23 by forming a potential barrier B expanding in the thickness direction of the light-absorbing layer 20 between adjacent pixels P. Accordingly, the pixel separator 23 is able to suppress movement of signal electric charges to adjacent pixels P across the potential barrier B.

Examples of the n-type impurity atom used for formation of the pixel separator 23 include Si, S, Sn, As, P, Ge, C, and the like. The pixel separator 23 may be formed by plasma doping of the light-absorbing layer 20 with a hydride gas of any of these impurity atoms. For example, the pixel separator 23 may be formed by plasma doping of the light-absorbing layer 20 with a gas of SiH₄, AsH₃, PH₃, GeH₄, or CH₄.

The insulating layer 41 includes an insulating material, and is provided to cover an inner portion of the opening 25. For example, the insulating layer 41 is provided to protect the light-absorbing layer 20 exposed in the opening 25. Specifically, the insulating layer 41 may be provided along a surface of the light-absorbing layer 20 exposed in the opening 25, and a side surface of the first semiconductor layer 21.

The insulating layer 41 may include an insulating material including one or more of Si, N, Al, Hf, Ta, Ti, Mg, O, La, Gd, or Y. For example, the insulating layer 41 may include SiN, SiO₂, SiON, AlON, SiAlN, MgO, Al₂O₃, AlSiO, HfO₂, HfAlO, or the like. In addition, the insulating layer 41 may have a thickness of 1 nm or greater to 500 nm, for example.

The protective layer 42 includes an insulating material, and is provided on a surface, on side opposite to a surface on which the light-absorbing layer 20 is stacked, of the first semiconductor layer 21. The protective layer 42 is provided in a region corresponding to the pixel P, and functions as a mask for protecting the first semiconductor layer 21 in a predetermined region during etching for formation of the opening 25. In addition, the protective layer 42 functions as a mask for protecting the first semiconductor layer 21 from the impurity atom during plasma doping for formation of the pixel separator 23.

The protective layer 42 may include an insulating material that includes one or more of Si, N, Al, Hf, Ta, Ti, Mg, O, La, Gd, or Y, for example. The protective layer 42 may include, for example, SiN, SiO₂, SiON, AlON, SiAlN, MgO, Al₂O₃, AlSiO, HfO₂, HfAlO, or the like. In addition, the protective layer 42 may have a thickness of 10 nm or greater to 5000 nm, for example.

The first electrode 31 is provided on a surface, on side opposite to a surface on which the light-absorbing layer 20 is stacked, of the first semiconductor layer 21 to penetrate through the protective layer 42. The first electrode 31 is a readout electrode that supplies a voltage for reading a signal electric charge photoelectrically converted in the light-absorbing layer 20. The first electrode 31 may read, for example, a hole as the signal electric charge from the light-absorbing layer 20. The electric charge read by the first electrode 31 is transferred to a pixel circuit or the like for performing signal processing through an unillustrated via, an unillustrated bump, or the like. The first electrode 31 may include, for example, a metal such as Ti, W, Pt, Au, Ge, Pd, Zn, Ni, In, or Al, or an alloy of any of these metals. The first electrode 31 may be provided as a single-layer film, or may be provided as a stacked film including a plurality of layers.

The second semiconductor layer 22 is provided on another main surface (that is, a light-receiving surface) of the light-absorbing layer 20 over the plurality of pixels P. The second semiconductor layer 22 is sandwiched between the light-absorbing layer 20 and the second electrode 32, and is a layer in which an electric charge to be discharged from the light-absorbing layer 20 to the second electrode 32 is moved. The second semiconductor layer 22 may include a compound semiconductor of the second electrical conductivity type (e.g., n-type). The second semiconductor layer 22 may include, for example, n-type InP having a larger band gap than that of the compound semiconductor included in the light-absorbing layer 20. The second semiconductor layer 22 may include, for example, Si, S, Sn, As, P, Ge, C, or the like as an n-type impurity atom.

The second electrode 32 is an electrode that discharges an electric charge that is not used as a signal electric charge of the electric charges photoelectrically converted in the light-absorbing layer 20. For example, in a case where a hole is read as the signal electric charge from the light-absorbing layer 20, the second electrode 32 may discharge an electron paired with the hole. Specifically, the second electrode 32 is provided as a common electrode for the plurality of pixels P, and is provided over the plurality of pixels P on a main surface, on side opposite to a main surface on which the light-absorbing layer 20 is stacked, of the second semiconductor layer 22. The second electrode 32 may use a transparent electrically conductive material having a transmittance of 50% or greater to light of a wavelength of 1600 nm to be provided as a transparent electrode that allows incident light such as infrared rays to pass therethrough. The second electrode 32 may be provided with use of, for example, ITO (Indium Tin Oxide), ITiO (In₂O₃—TiO₂), or the like.

In a method of manufacturing the photoelectric conversion device 11 according to the present embodiment, using plasma doping makes it possible to form the pixel separator 23, which expands in the thickness direction of the light-absorbing layer 20, on the light-absorbing layer 20 exposed in the opening 25 that separates the pixels P. Accordingly, in the photoelectric conversion device 11, it is possible to expand the potential barrier B by the pixel separator 23 to a deeper region of the light-absorbing layer 20, which makes it possible to more firmly suppress movement of signal electric charges between the pixels P. Thus, it is possible for the photoelectric conversion device 11 according to the present embodiment to more firmly suppress crosstalk between pixels.

### 1.2. Manufacturing Method Example

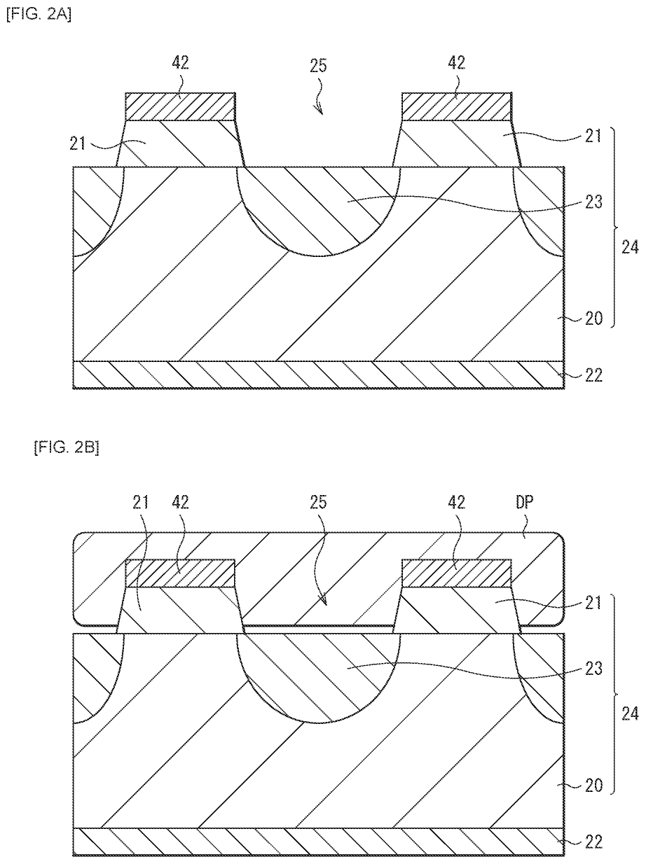

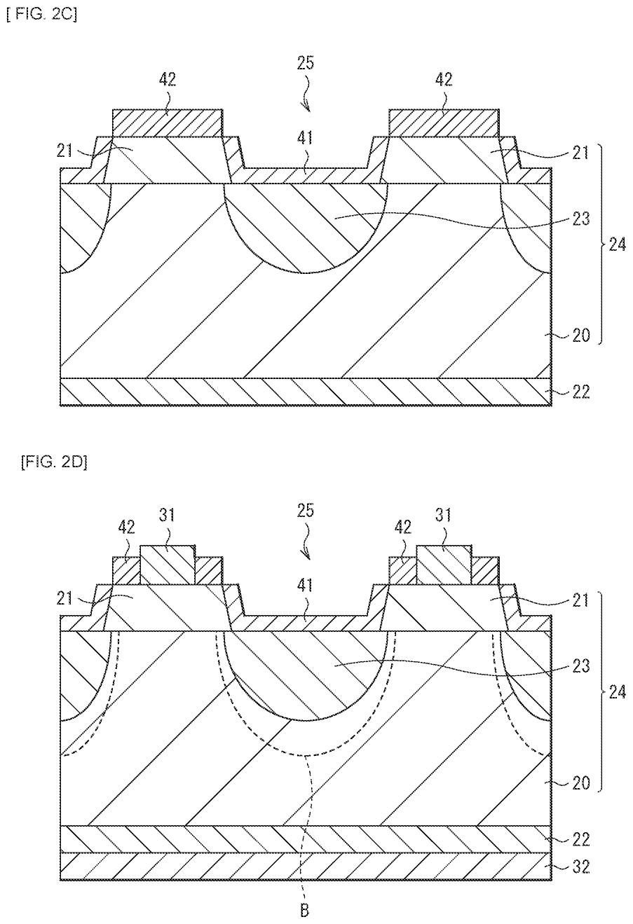

Next, description is given of a method of manufacturing the photoelectric conversion device 11 according to the present embodiment with reference to FIGS. 2A to 2D. FIGS. 2A to 2D are vertical cross-sectional views that describe each of processes of the method of manufacturing the photoelectric conversion device 11 according to the present embodiment.

First, as illustrated in FIG. 2A, a stacking structure including the photoelectric conversion structure 24 is formed. Thereafter, the first semiconductor layer 21 of the photoelectric conversion structure 24 is etched to form the opening 25.

Specifically, the second semiconductor layer 22, the light-absorbing layer 20, and the first semiconductor layer 21 are epitaxially grown to form the stacking structure including the photoelectric conversion structure 24. For example, the stacking structure including the photoelectric conversion structure 24 may be formed by epitaxially growing n-InGaAs (the light-absorbing layer 20) and p-InP (the first semiconductor layer 21) on an InP substrate (the second semiconductor layer 22). Subsequently, the protective layer 42 that covers a region corresponding to each pixel P is formed on the first semiconductor layer 21, and the first semiconductor layer 21 is etched with use of the protective layer 42 as a mask to form the opening 25 that exposes the light-absorbing layer 20.

Subsequently, as illustrated in FIG. 2B, the pixel separator 23 is formed on the light-absorbing layer 20 exposed in the opening 25 by plasma doping using a source gas including an impurity atom of the second electrical conductivity type. Specifically, the light-absorbing layer 20 exposed in the opening 25 is exposed to plasma DP of a SiH₄ gas including Si that is an impurity atom of the second electrical conductivity type to form the pixel separator 23 doped with Si. Furthermore, the pixel separator 23 is able to activate the added Si by heat treatment by a H (hydrogen) radical included in the plasma DP of the SiH₄ gas.

It is to be noted that it is also possible to form the pixel separator 23 by diffusing As, P, Ge, or C as the impurity atom of the second electrical conductivity type into the light-absorbing layer 20. In such a case, as a source gas for plasma doping, it is possible to use AsH₃, PH₃, GeH₄, CH₄, or the like.

In plasma doping, adjusting a process parameter makes it possible to easily control a doping profile of the impurity atom for the light-absorbing layer 20. Accordingly, using plasma doing makes it possible to easily form the pixel separator 23 to a deeper region of the light-absorbing layer 20, which makes it possible for the photoelectric conversion device 11 to further suppress crosstalk between the pixels P.

Next, as illustrated in FIG. 2C, the insulating layer 41 is formed inside the opening 25. Specifically, SiN, SiO, polysilicon or the like is deposited on a surface of the light-absorbing layer 20 inside the opening 25 and a side surface of the first semiconductor layer 21 with use of an ALD (Atomic Layer Deposition) method, a Cyclic-CVD (Chemical Vapor Deposition) method, a sputtering method, or the like to form the insulating layer 41.

Thereafter, as illustrated in FIG. 2D, the first electrode 31 and the second electrode 32 are formed. Specifically, lithography and etching are used to form, in the protective layer 42, a through hole that reaches the first semiconductor layer 21. Subsequently, a metal such as W or an alloy is embedded in the formed through hole to form the first electrode 31. In addition, ITO or the like that is a transparent electrically conductive material is deposited on the main surface (that is, the light-receiving surface), on side opposite to the main surface provided with the light-absorbing layer 20, of the second semiconductor layer 22 with use of sputtering or the like to form the second electrode 32.

Using the above manufacturing method makes it possible to form the photoelectric conversion device 11 according to the present embodiment. In the method of manufacturing the photoelectric conversion device 11 according to the present embodiment, adjusting the process parameter of the plasma doping makes it possible to easily control the doping profile of the impurity atom that is to be introduced into the light-absorbing layer 20. This make it possible to easily form the pixel separator 23 to a deeper region in the thickness direction of the light-absorbing layer 20 in the photoelectric conversion device 11, which makes it possible to more firmly suppress movement of signal electric charges between the pixels P. Thus, it is possible for the photoelectric conversion device 11 to more firmly suppress crosstalk between the pixels P.

### 1.3. Modification Example

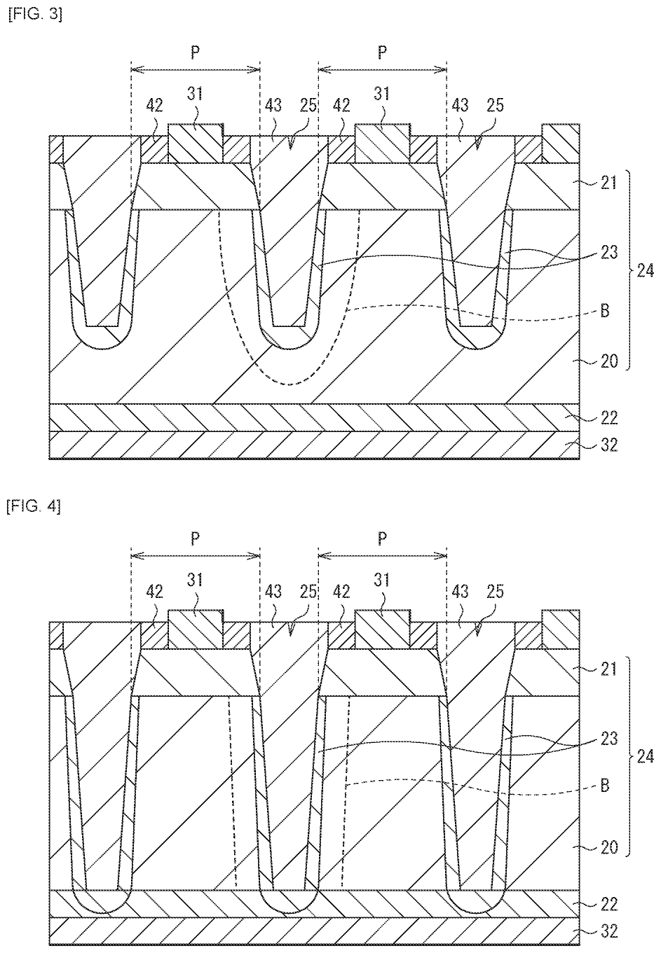

Next, description is given of a modification example of the photoelectric conversion device 11 according to the present embodiment with reference to FIGS. 3 and 4. FIG. 3 is a vertical cross-sectional view of an example of a cross-sectional configuration of the photoelectric conversion device 11 according to the modification example. FIG. 4 is a vertical cross-sectional view of another example of the cross-sectional configuration of the photoelectric conversion device 11 according to the modification example.

As illustrated in FIG. 3, the opening 25 may be provided to penetrate through a portion of the light-absorbing layer 20 in addition to the first semiconductor layer 21. Alternatively, as illustrated in FIG. 4, the opening 25 may be provided to penetrate through the first semiconductor layer 21 and the light-absorbing layer 20.

In such cases, the pixel separator 23 is provided on the light-absorbing layer 20 exposed on a side surface or a bottom surface of the opening 25. This makes it possible to provide the pixel separator 23 to extend in the thickness direction of the light-absorbing layer 20 along the side surface of the opening 25 dug in the thickness direction of the light-absorbing layer 20. Accordingly, it is possible to form the potential barrier B to a deeper region in the thickness direction of the light-absorbing layer 20, which makes it possible for the photoelectric conversion device 11 according to the modification example to more firmly suppress crosstalk between the pixels P.

After forming the pixel separator 23 on the light-absorbing layer 20 by plasma doping, an embedded insulating layer 43 may be embedded in the opening 25 that penetrates through the first semiconductor layer 21 and a portion or the entirety of the light-absorbing layer 20. The embedded insulating layer 43 embedded in the opening 25 may include, for example, an insulating material including one or more of Si, N, Al, Hf, Ta, Ti, Mg, O, La, Gd, or Y, as with the insulating layer 41 and the protective layer 42. For example, the embedded insulating layer 43 may include SiN, SiO₂, SiON, AlON, SiAlN, MgO, Al₂O₃, AlSiO, HfO₂, HfAlO, or the like. In such a case, the pixel separator 23 is expected to have an effect of suppressing a dark current generated at an interface between the light-absorbing layer 20 and the embedded insulating layer 43.

### 2. SECOND EMBODIMENT

### 2.1. Configuration Example

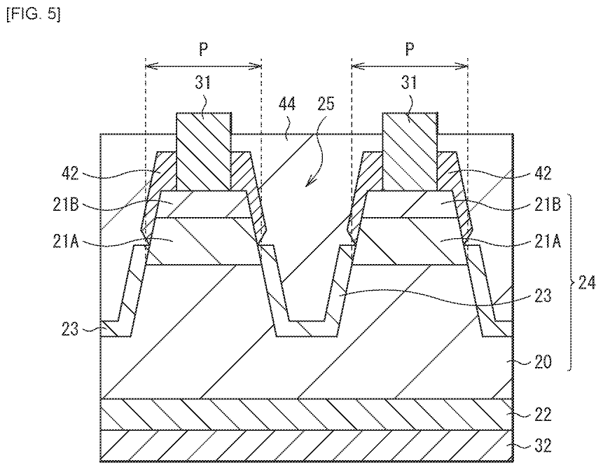

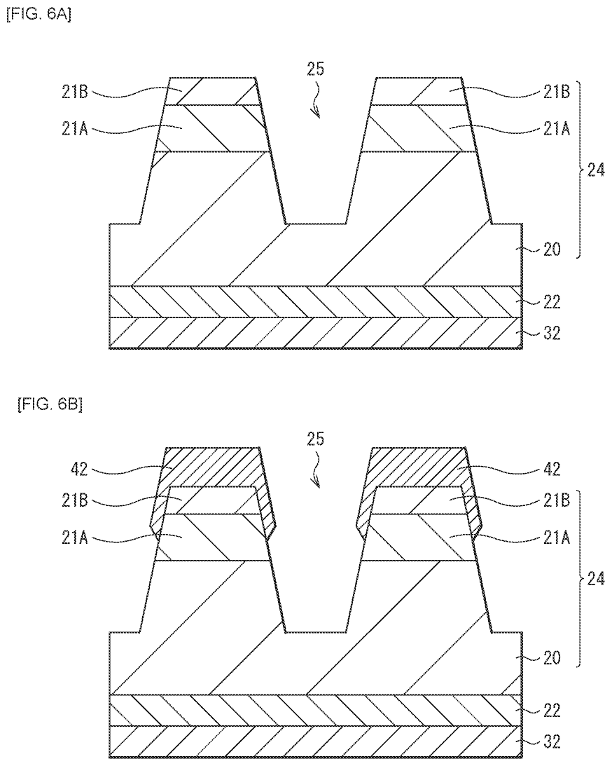

Next, description is given of a configuration example of a photoelectric conversion device according to a second embodiment of the present disclosure with reference to FIG. 5. FIG. 5 is a vertical cross-sectional view of an example of a cross-sectional configuration of a photoelectric conversion device 12 according to the present embodiment.

As illustrated in FIG. 5, the photoelectric conversion device 12 includes, for example, the light-absorbing layer 20, the pixel separator 23, first semiconductor layers 21A and 21B, the first electrode 31, the second semiconductor layer 22, the second electrode 32, the protective layer 42, and an embedded insulating layer 44. In the present embodiment, the light-absorbing layer 20, and the first semiconductor layers 21A and 21B that are stacked on one main surface (that is, the no-light-receiving surface) of the light-absorbing layer 20 are also collectively referred to as the photoelectric conversion structure 24.

The photoelectric conversion device 12 is able to photoelectrically convert, for example, light of a wavelength ranging from a visible light region (e.g., 380 nm or greater and less than 780 nm) to a near-infrared region (e.g., 780 nm or greater and less than 2400 nm), as with the photoelectric conversion device 11 according to the first embodiment. In addition, in the photoelectric conversion device 12, the pixel P is provided for each first semiconductor layer 21A, each first semiconductor layer 21B, and each first electrode 31 that are provided separately from each other, and a signal electric charge is read for each pixel P from the first electrode 31.

The light-absorbing layer 20 is a layer that absorbs light of a predetermined wavelength to generate signal electric charges. The light-absorbing layer 20 includes, for example, a compound semiconductor of the second electrical conductivity type (e.g., n-type), and is provided over a plurality of pixels P. Specifically, the light-absorbing layer 20 may include an n-type III-V group compound semiconductor including one or more of In, Ga, Al, As, P, Sb, or N. For example, the light-absorbing layer 20 may include n-type InGaAs. In addition, the light-absorbing layer 20 may include, for example, Si, S, Sn, As, P, Ge, C, or the like as an n-type impurity atom. The concentration of the n-type impurity atom in the light-absorbing layer 20 may be, for example, 1×10¹⁴ cm⁻³ to 1×10¹⁷ cm⁻³. The light-absorbing layer 20 may have, for example, a thickness of 100 nm to 10000 nm.

The first semiconductor layers 21A and 21B are provided for each pixel P separately by the opening 25 on one main surface (that is, the non-light-receiving surface) of the light-absorbing layer 20, for example. The first semiconductor layers 21A and 21B are sandwiched between the light-absorbing layer 20 and the first electrode 31, and are layers in which a signal electric charge to be read from the light-absorbing layer 20 to the first electrode 31 is moved. In order to more easily read the signal electric charge to the first electrode 31, the first semiconductor layers 21A and 21B are provided as layers that are different in density of the p-type impurity atom from each other. Specifically, the first semiconductor layer 21B provided on side of the first electrode 31 may be provided as a layer having a higher concentration of the p-type impurity atom than the first semiconductor layer 21A provided on side of the light-absorbing layer 20.

The first semiconductor layers 21A and 21B may include a compound semiconductor of the first electrical conductivity type (e.g., p-type). The first semiconductor layers 21A and 21B may include, for example, p-type InP having a larger band gap than that of the compound semiconductor included in the light-absorbing layer 20. The first semiconductor layers 21A and 21B may include, for example, Zn, Ng, Be, or the like as a p-type impurity atom.

In the photoelectric conversion device 12 according to the present embodiment, the opening 25 is provided to penetrate through the first semiconductor layers 21A and 21B of the photoelectric conversion structure 24 and dig into a portion of the light-absorbing layer 20. For example, the opening 25 may be formed by etching the first semiconductor layers 21A and 21B and a portion of the light-absorbing layer 20, and may expose the light-absorbing layer 20 on the bottom surface and the side surface of the opening 25.

The pixel separator 23 is a region of the second electrical conductivity type (e.g., n-type), and is provided on the light-absorbing layer 20 exposed on the side surface or the bottom surface of the opening 25 to extend in the thickness direction of the light-absorbing layer 20. Specifically, the pixel separator 23 may be provided to extend in the thickness direction of the light-absorbing layer 20 along the side surface of the opening 25 that is dug in the thickness direction of the light-absorbing layer 20.

In the present embodiment, the pixel separator 23 is formed by epitaxially growing a compound semiconductor including an impurity atom of the second electrical conductivity type (e.g., n-type). Specifically, the pixel separator 23 may be formed by selectively epitaxially growing, on the light-absorbing layer 20 inside the opening 25, n-type InP having a larger band gap than that of the compound semiconductor included in the light-absorbing layer 20. The pixel separator 23 may include, for example, Si, S, Sn, As, P, Ge, C, or the like as the n-type impurity atom.

The pixel separator 23 is able to induce electric charges to a region below the first semiconductor layers 21A and 21B surrounded by the pixel separator 23 by forming the potential barrier B expanding in the thickness direction of the light-absorbing layer 20 between adjacent pixels P. Accordingly, the pixel separator 23 is able to suppress movement of signal electric charges to adjacent pixels P across the potential barrier B.

The protective layer 42 includes an insulating material, and is provided on the first semiconductor layers 21A and 21B to cover the first semiconductor layers 21A and 21B. The protective layer 42 is provided on the first semiconductor layers 21A and 21B to function as a mask upon selectively epitaxially growing the pixel separator 23. The protective layer 42 may include an insulating material that includes one or more of Si, N, Al, Hf, Ta, Ti, Mg, O, La, Gd, or Y, for example. The protective layer 42 may include, for example, SiN, SiO₂, SiON, AlON, SiAlN, MgO, Al₂O₃, AlSiO, HfO₂, HfAlO, or the like.

The embedded insulating layer 44 includes an insulating material, and flattens asperities caused by the opening 25 by being embedded in the opening 25 that penetrates through the first semiconductor layers 21A and 21B and a portion of the light-absorbing layer 20. The embedded insulating layer 44 may include, for example, an insulating material including one or more of Si, N, Al, Hf, Ta, Ti, Mg, O, La, Gd, or Y, as with the protective layer 42. For example, the embedded insulating layer 44 may include SiN, SiO₂, SiON, AlON, SiAlN, MgO, Al₂O₃, AlSiO, HfO₂, HfAlO, or the like.

The first electrode 31 is provided on the first semiconductor layer 21B to penetrate through the protective layer 42. The first electrode 31 is a readout electrode that supplies a voltage for reading a signal electric charge photoelectrically converted in the light-absorbing layer 20. The first electrode 31 may read, for example, a hole as the signal electric charge from the light-absorbing layer 20. The electric charge read by the first electrode 31 is transferred to a pixel circuit or the like for performing signal processing through an unillustrated via, an unillustrated bump, or the like. The first electrode 31 may include, for example, a metal such as Ti, W, Pt, Au, Ge, Pd, Zn, Ni, In, or Al, or an alloy of any of these metals. The first electrode 31 may be provided as a single-layer film, or may be provided as a stacked film including a plurality of layers.

The second semiconductor layer 22 is provided on another main surface (that is, the light-receiving surface) of the light-absorbing layer 20 over the plurality of pixels P. The second semiconductor layer 22 is sandwiched between the light-absorbing layer 20 and the second electrode 32, and is a layer in which an electric charge to be discharged from the light-absorbing layer 20 to the second electrode 32 is moved. The second semiconductor layer 22 may include a compound semiconductor of the second electrical conductivity type (e.g., n-type). The second semiconductor layer 22 may include, for example, n-type InP having a larger band gap than that of the compound semiconductor included in the light-absorbing layer 20. The second semiconductor layer 22 may include, for example, Si, S, Sn, As, P, Ge, C, or the like as an n-type impurity atom.

The second electrode 32 is an electrode that discharges an electric charge that is not used as a signal electric charge of the electric charges photoelectrically converted in the light-absorbing layer 20. For example, in a case where a hole is read as the signal electric charge from the light-absorbing layer 20, the second electrode 32 may discharge an electron paired with the hole. Specifically, the second electrode 32 is provided as a common electrode for the plurality of pixels P, and is provided over the plurality of pixels P on the main surface, on side opposite to the main surface on which the light-absorbing layer 20 is stacked, of the second semiconductor layer 22. The second electrode 32 may use a transparent electrically conductive material having a transmittance of 50% or greater to light of a wavelength of 1600 nm to be provided as a transparent electrode that allows incident light such as infrared rays to pass therethrough. The second electrode 32 may be provided with use of, for example, ITO (Indium Tin Oxide), ITiO (In₂O₃—TiO₂), or the like.

In a method of manufacturing the photoelectric conversion device 12 according to the present embodiment, using selective epitaxial growth of a semiconductor compound makes it possible to form the pixel separator 23 on the light-absorbing layer 20 exposed on the side surface and the bottom surface of the opening 25 that separates the pixels P. Accordingly, in the photoelectric conversion device 12, it is possible to expand a potential barrier to a deeper region of the light-absorbing layer 20 along the opening 25 dug in the thickness direction of the light-absorbing layer 20, which makes it possible to more firmly suppress movement of signal electric charges between the pixels P. Thus, it is possible for the photoelectric conversion device 12 according to the present embodiment to more firmly suppress crosstalk between pixels.

### 2.2. Manufacturing Method Example

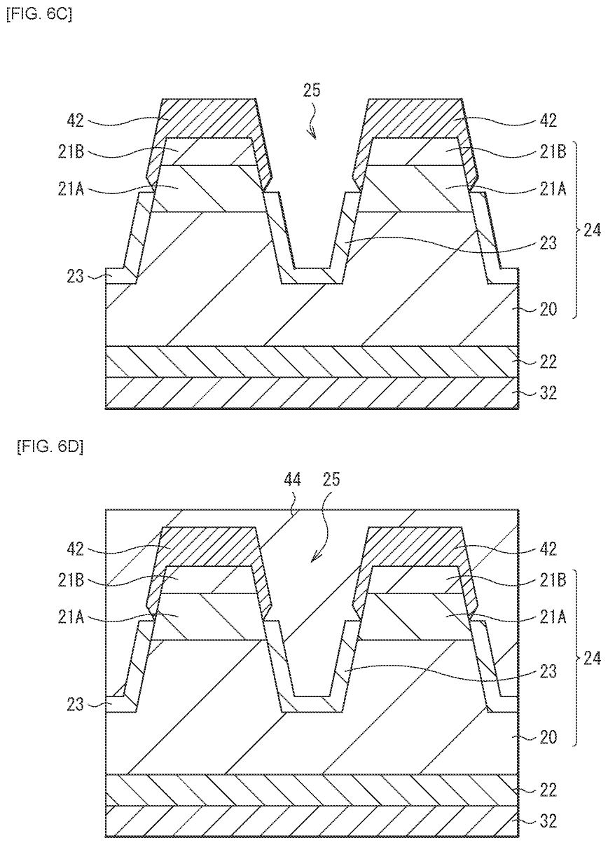

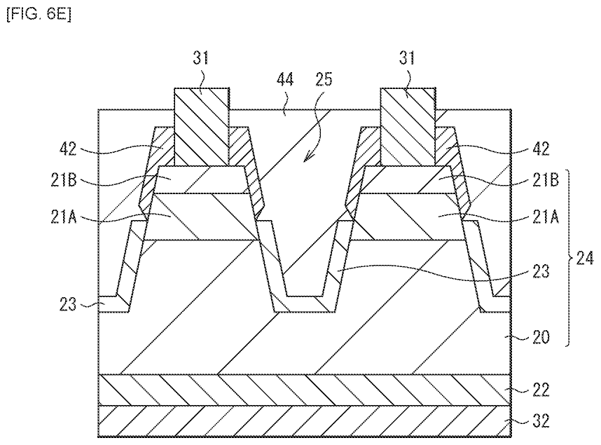

Next, description is given of a method of manufacturing the photoelectric conversion device 12 according to the present embodiment with reference to FIGS. 6A to 6E. FIGS. 6A to 6E are vertical cross-sectional views that describe each of processes of the method of manufacturing the photoelectric conversion device 12 according to the present embodiment. First, as illustrated in FIG. 6A, a stacking structure including the photoelectric conversion structure 24 is formed. Thereafter, the first semiconductor layers 21A and 21B of the photoelectric conversion structure 24, and a portion of the light-absorbing layer 20 are etched to form the opening 25.

Specifically, the light-absorbing layer 20 and the first semiconductor layers 21A and 21B are epitaxially grown on the second semiconductor layer 22 to form the stacking structure including the photoelectric conversion structure 24. For example, the stacking structure including the photoelectric conversion structure 24 may be formed by epitaxially growing n-InGaAs (the light-absorbing layer 20), p−InP (the first semiconductor layer 21A), and p+InP (the first semiconductor layer 21B) on an InP substrate (the second semiconductor layer 22). Subsequently, the first semiconductor layers 21A and 21B and a portion of the light-absorbing layer 20 are etched with use of a mask that covers a region corresponding to each pixel P to form the opening 25 that digs into the portion of the light-absorbing layer 20.

It is to be noted that ITO or the like that is a transparent electrically conductive material may be deposited in advance on the main surface (that is, the light-receiving surface), on side opposite to the main surface provided with the light-absorbing layer 20, of the second semiconductor layer 22 with use of sputtering or the like. Thus, the second electrode 32 may be formed as a transparent electrode.

Subsequently, as illustrated in FIG. 6B, after an insulating material such as SiN is deposited on the first semiconductor layers 21A and 21B, the insulating material deposited on the opening 25 is removed. Thus, the protective layer 42 that covers the first semiconductor layers 21A and 21B is formed.

Next, as illustrated in FIG. 6C, an n-type compound semiconductor (e.g., n−InP) is selectively epitaxially grown on the light-absorbing layer 20 exposed on an inner side surface and an inner bottom surface of the opening 25 to form the pixel separator 23. Examples of the n-type impurity atom include Si, S, Sn, As, P, Ge, C, and the like. The pixel separator 23 may be formed by epitaxially growing InP while taking these impurity atoms.

Subsequently, as illustrated in FIG. 6D, the embedded insulating layer 44 is formed to be embedded in the opening 25 in which the pixel separator 23 is formed. Specifically, SiO₂ is deposited with use of a CVD (Chemical Vapor Deposition) method or the like to be embedded in the opening 25 in which the pixel separator 23 is formed. Thereafter, a surface of the embedded insulating layer 44 is flattened with use of etching back, a CMP (Chemical mechanical polishing) method, or the like.

Thereafter, as illustrated in FIG. 6E, the first electrode 31 that penetrates through the protective layer 42 is formed. Specifically, a through hole that reaches the first semiconductor layer 21B is formed in the protective layer 42 with use of lithography and etching. Subsequently, a metal such as W or an alloy is embedded in the formed through hole to form the first electrode 31.

Using the above manufacturing method makes it possible to form the photoelectric conversion device 12 according to the present embodiment. In the method of manufacturing the photoelectric conversion device 12 according to the present embodiment, it is possible to form the pixel separator 23 including an n-type compound semiconductor with use of selective epitaxial growth, which makes it possible to form the pixel separator 23 in a more appropriate region. Accordingly, in the photoelectric conversion device 12, it is possible to separately form the pixel separator 23 that is the n-type and the first semiconductor layers 21A and 21B that are the p-type on the light-absorbing layer 20. This makes it possible for the photoelectric conversion device 12 to suppress crosstalk between the pixels P and reduce a dark current by the pixel separator 23while achieving favorable contact characteristics to the first electrode 31 by the first semiconductor layers 21A and 21B.

### 2.3. Modification Examples

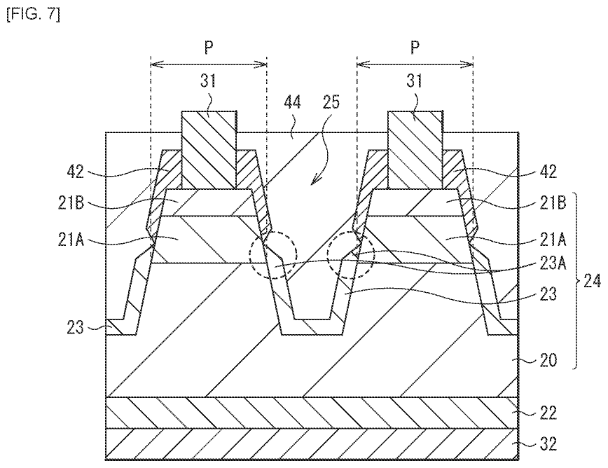

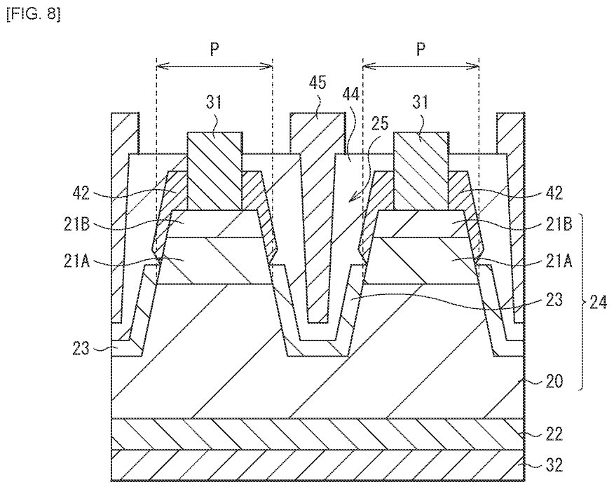

Next, description is given of modification examples of the photoelectric conversion device 12 according to the present embodiment with reference to FIGS. 7 and 8. FIG. 7 is a vertical cross-sectional view of an example of a cross-sectional configuration of the photoelectric conversion device 12 according to a first modification example. FIG. 8 is a vertical cross-sectional view of an example of a cross-sectional configuration of the photoelectric conversion device 12 according to a second modification example.

### First Modification Example

As illustrated in FIG. 7, the pixel separator 23 may further include a facet section 23A at an upper end. The facet section 23A is provided at the upper end of the pixel separator 23 epitaxially grown on the inner side surface of the opening 25, and has a shape having a chamfered corner (a cut off corner) at the upper end. Having the facet section 23A makes it possible for the pixel separator 23 of the n-type to reduce the volume of a depletion layer formed between the first semiconductor layers 21A and 21B of the P-type. This makes it possible for the pixel separator 23 to further suppress generation of a dark current.

### Second Modification Example

As illustrated in FIG. 8, in the opening 25, a metal layer 25 may be further provided in addition to the embedded insulating layer 44. The metal layer 45 includes a metal such as W, and is provided not to be in contact with the first semiconductor layers 21A and 21B and the pixel separator 23. Specifically, after embedding the embedded insulating layer 44 in the opening 25, the metal layer 45 may be formed by providing a through hole in a region corresponding to the opening 25 not to be in contact with the pixel separator 23 and embedding a metal such as W in the through hole. Providing the metal layer 45 makes it possible for the photoelectric conversion device 12 to more firmly suppress crosstalk between the pixels P.

### 3. THIRD EMBODIMENT

### 3.1. Configuration Example

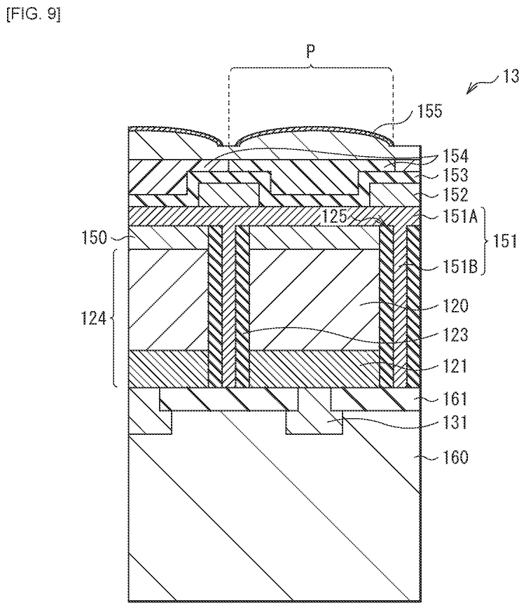

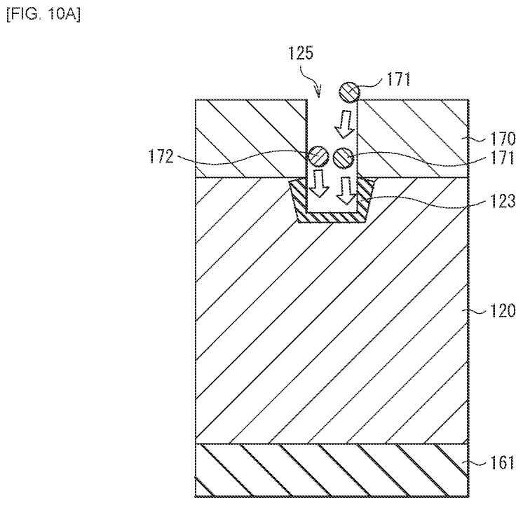

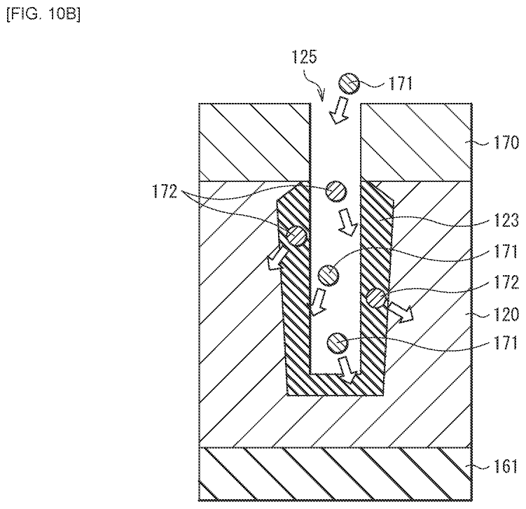

Next, description is given of a configuration example of a photoelectric conversion device 13 according to a third embodiment of the present disclosure with reference to FIG. 9. FIG. 9 is a vertical cross-sectional view of an example of a cross-sectional configuration of the photoelectric conversion device 13 according to the present embodiment.

As illustrated in FIG. 9, the photoelectric conversion device 13 includes, for example, a multilayer wiring substrate 160, a first electrode 131, a first protective layer 161, a first semiconductor layer 121, a light-absorbing layer 120, a pixel separator 123, a substrate 150, an insulating layer 151, a light-shielding structure 152, a second protective layer 153, a color filter 154, and an on-chip lens 155. In the present embodiment, the light-absorbing layer 20, and the first semiconductor layer 121 provided on one main surface (that is, a non-light-receiving surface) of the light-absorbing layer 20 are also collectively referred to as a photoelectric conversion structure 124.

The photoelectric conversion device 13 is able to photoelectrically convert, for example, light of a wavelength ranging from a visible light region (e.g., 380 nm or greater and less than 780 nm) to a near-infrared region (e.g., 780 nm or greater and less than 2400 nm). The photoelectric conversion device 13 includes a plurality of pixels P two-dimensionally arranged, and is able to read a signal electric charge photoelectrically converted for each pixel P.

The substrate 150 includes, for example, a compound semiconductor of the first electrical conductivity type (e.g., p-type) or the second electrical conductivity type (e.g., n-type). Specifically, the substrate 150 may be an n-type InP substrate. The substrate 150 may include, for example, Si, S, Sn, As, P, Ge, C, or the like as an n-type impurity atom.

The light-absorbing layer 120 is a layer that absorbs light of a predetermined wavelength to generate signal electric charges. The light-absorbing layer 120 is a layer provided common to the plurality of pixels P, and is contiguously provided over the plurality of pixels P on one main surface (that is, a non-light-receiving surface) of the substrate 150. The light-absorbing layer 120 may include, for example, a III-V group compound semiconductor. Specifically, the light-absorbing layer 120 may include n-type InGaAs (indium gallium arsenide). In addition, the light-absorbing layer 120 may include Si, S, Sn, As, P, Ge, C, or the like as an n-type impurity.

In the photoelectric conversion device 13 according to the present embodiment, the opening 125 is provided to penetrate through the light-absorbing layer 120 of the photoelectric conversion structure 124. For example, the opening 125 may be formed by etching the substrate 150 and the light-absorbing layer 120, and the light-absorbing layer 120 may be exposed on a side surface of the opening 125.

The pixel separator 123 is provided between adjacent pixels P to extend in a thickness direction of the light-absorbing layer 120. Specifically, the pixel separator 123 is provided to extend in the thickness direction of the light-absorbing layer 120 along the side surface of the opening 125 that is provided to penetrate through the substrate 150 and the light-absorbing layer 120 in the thickness direction. Accordingly, the pixel separator 123 is able to suppress movement of signal electric charges between the pixels P through the light-absorbing layer 120. For example, the pixel separator 123 may be provided by introducing an impurity atom of the second electrical conductivity type (e.g., n-type) at a high concentration into the light-absorbing layer 120 through the opening 125. Examples of the n-type impurity atom introduced into the pixel separator 123 may include Si, S, Sn, As, P, Ge, C, and the like.

In the present embodiment, upon forming the opening 125 in the light-absorbing layer 120 by etching or the like, the pixel separator 123 is formed by also introducing the n-type impurity atom into a chamber in which the etching is performed. Specifically, the pixel separator 123 may be formed concurrently with formation of the opening 125 by repeatedly executing etching on the light-absorbing layer 120 and diffusion and activation of the impurity atom in the same chamber. In such etching, a temperature for heat treatment is adjustable, and it is possible to execute such etching in an etching apparatus that enables plasma etching.

Accordingly, it is possible to form the pixel separator 123 while controlling a concentration gradient of the impurity atom in the thickness of the light-absorbing layer 120. In addition, the pixel separator 123 is formed concurrently with the opening 125, which makes it possible to reduce process damage to the light-absorbing layer 120.

For example, it is possible to use C, Si, S, Sn, or the like as the n-type impurity atom. These n-type impurity atoms may be introduced into the pixel separator 123 during etching by using a CF-based gas, a CO-based gas, a SiF-based gas, a SiCl-based gas, SF₆-based gas, or a COS gas, for example.

In addition, the pixel separator 123 may be formed by introducing a p-type impurity atom in place of the n-type impurity atom. It is possible to use Zn, Mg, Be, or the like as the p-type impurity atom. These p-type impurity atoms may be introduced into the pixel separator 123 during etching by using a Zn(CH₂)₂ gas, for example.

The first semiconductor layer 121 is provided for each pixel P on one main surface (that is, the non-light-receiving surface) of the light-absorbing layer 120, for example. The first semiconductor layer 121 is provided between the light-absorbing layer 120 and the first electrode 131, and is a layer in which a signal electric charge to be read from the light-absorbing layer 120 to the first electrode 131 is moved. The first semiconductor layer 121 may include a compound semiconductor of the first electrical conductivity type (e.g., p-type). The first semiconductor layer 121 may include, for example, p-type InP having a larger band gap than that of the compound semiconductor included in the light-absorbing layer 120. The first semiconductor layer 121 may include, for example, Zn, Ng, Be, or the like as a p-type impurity atom.

The first protective layer 161 includes an insulating material, and is provided between the first semiconductor layer 121 and the multilayer wiring substrate 160. For example, the first protective layer 161 may include an insulating material such as SiN, SiO₂, SiON, AlON, SiAlN, MgO, Al₂O₃, AlSiO, HfO₂, or HfAlO. The first protective layer 161 is provided with an opening for each pixel P, and a signal electric charge is read from the light-absorbing layer 120 through the first electrode 131 provided in the opening.

The first electrode 131 is provided to penetrate through the first protective layer 161, and is electrically coupled to the first semiconductor layer 121. The first electrode 131 is provided for each pixel P, and supplies a voltage for reading a signal electric charge generated in the light-absorbing layer 120, and outputs the read signal electric charge to a pixel circuit (not illustrated) or the like provided in the multilayer wiring substrate 160. One first electrode 131 may be provided for each pixel P, or a plurality of first electrodes 131 may be provided for each pixel P.

The first electrode 131 may include, for example, a metal such as Ti, W, Pt, Au, Ge, Pd, Zn, Ni, In, or Al, or an alloy of any of these metals. The first electrode 131 may be provided as a single-layer film, or may be provided as a stacked film including a plurality of layers.

The multilayer wiring substrate 160 includes a predetermined circuit, and is provided by stacking an insulating layer and a wiring layer. For example, the multilayer wiring substrate 160 may include, for each or every two or more of pixels, a pixel circuit or the like that processes a signal electric charge read from each of the pixels P.

The insulating layer 151 includes an embedded insulating layer 151A that is embedded in the opening 125, and an interlayer insulating layer 151B that is provided on a main surface (that is, a light-receiving surface), on side opposite to the main surface provided with the light-absorbing layer 120, of the substrate 150. The embedded insulating layer 151A is embedded in the opening 125 that is provided to penetrate through the substrate 150, the light-absorbing layer 120, and the first semiconductor layer 121. In addition, the interlayer insulating layer 151B is provided over the entire main surface, on side opposite to the main surface provided with the light-absorbing layer 120, of the substrate 150 to flatten asperities caused by the opening 125 and the like. The insulating layer 151 may include, for example, an insulating material such as SiN, SiO₂, SiON, AlON, SiAlN, MgO, Al₂O₃, AlSiO, HfO₂, or HfAlO.

The light-shielding structure 152 is provided on the interlayer insulating layer 151B between the pixels P, and prevents generation of crosstalk between adjacent pixels P by obliquely incident light. Specifically, the light-shielding structure 152 may be provided on the interlayer insulating layer 151B in a region corresponding to the opening 125 that separates the adjacent pixels P from each other. The light-shielding structure 152 may include, for example, a metal such as Ti, W, Pt, Au, or Cr, or an alloy or a metal compound of any of these metals, or may include an organic material such as carbon. In addition, the light-shielding structure 152 may be provided as a single-layer film, or may be provided as a stacked film including a plurality of materials. The second protective layer 153 is provided over an entire main surface (that is, a light-receiving surface), on side opposite to a main surface provided with the substrate 150, of the interlayer insulating layer 151B to cover the light-shielding structure 152. The second protective layer 153 protects respective components of the photoelectric conversion device 13 from an external environment. The second protective layer 153 may include, for example, an insulating material such as SiN, SiO₂, SiON, AlON, SiAlN, MgO, Al₂O₃, AlSiO, HfO₂, or HfAlO.

The color filter 154 is, for example, a red filter, a green filter, a blue filter, a white filter, an IR (InfraRed) filter, or the like, and is provided on the second protective layer 153. The color filter 154 is able to control the wavelength or the like of light incident on the light-absorbing layer 120 by allowing light in a predetermined wavelength region to pass therethrough, or by absorbing the light. The color filter 154 may be provided for each pixel P on the basis of a predetermined regular arrangement (e.g., a Bayer arrangement).

The on-chip lens 155 has a function of concentrating light onto the light-absorbing layer 120 provided for each pixel P. The on-chip lens 155 may include, for example, an organic material such as an acrylic resin or an inorganic material such as silicon oxide.

In a method of manufacturing the photoelectric conversion device 13 according to the present embodiment, a gas including an impurity atom of the second electrical conductivity type is introduced concurrently with etching the light-absorbing layer 120 for formation of the opening 125. Accordingly, in the photoelectric conversion device 13, it is possible to form the pixel separator 123 that expands in the thickness direction of the light-absorbing layer 120 along the side surface of the opening 125. In addition, in the photoelectric conversion device 13, the introduction amount of the gas including the impurity atom of the second conductivity type is controlled with an increase in the digging amount of the opening 125, which makes it possible to form the pixel separator 123 having a concentration gradient of the impurity atom in the thickness direction of the light-absorbing layer 120. Furthermore, in the photoelectric conversion device 13, it is possible to concurrently perform formation of the opening 125 and formation of the pixel separator 123, which makes it possible to reduce the number of steps of a manufacturing process.

### 3.2. Manufacturing Method Example

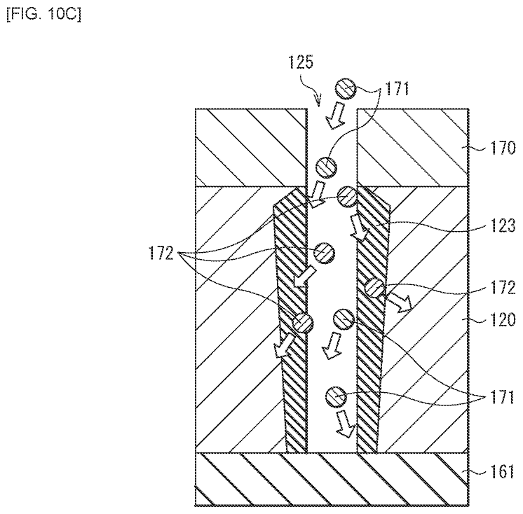

Next, description is given of a method of forming the pixel separator 123 in the photoelectric conversion device 13 according to the present embodiment with reference to FIGS. 10A to 10C. FIGS. 10A to 10C are vertical cross-sectional views that describe, step by step, formation of the pixel separator 123 in the photoelectric conversion device 13.

As illustrated in FIG. 10A, the light-absorbing layer 120 is etched with use of a mask 170 that covers a region other than a region in which the opening 125 is to be formed. At this time, in a method of manufacturing the photoelectric conversion device 13 according to the present embodiment, etching is performed by introducing a gas including an impurity atom 172 of the second electrical conductivity type (e.g., n-type) in addition to an etching gas. Accordingly, in addition to an etching atom 171 included in the etching gas, the n-type impurity atom 172 is applied to the light-absorbing layer 120, thereby forming the opening 125 and diffusing the n-type impurity atom 172 into the light-absorbing layer 120 on a bottom surface and the side surface of the opening 125.

Thereafter, as illustrated in FIGS. 10B and 10C, etching on the light-absorbing layer 120 progresses, and the opening 125 is formed to sequentially extend in the thickness direction of the light-absorbing layer 120. In association with this, the pixel separator 123 is sequentially formed on the side surface and the bottom surface of the formed opening 125 by diffusing the n-type impurity atom 172.

The pixel separator 123 may be formed by repeatedly performing formation of the opening 125 and heat diffusion of the impurity atom 172, or may be formed by forming the entire opening 125 and thereafter collectively performing heat diffusion of the impurity atom 172 into the opening 125. It is possible to control a concentration profile of the impurity atom 172 included in the pixel separator 123 by adjusting the flow rate of the gas including the impurity atom 172 to be introduced during etching and time of heat diffusion of the impurity atom 172. Accordingly, in a case where the pixel separator 123 is formed by repeatedly performing formation of the opening 125 and heat diffusion of the impurity atom 172, the pixel separator 123 is able to have a concentration profile of the impurity atom 172 having a gradient in the thickness direction of the light-absorbing layer 120.

Using the above manufacturing method makes it possible to form the pixel separator 123 in the photoelectric conversion device 13 according to the present embodiment. In the method of manufacturing the photoelectric conversion device 13 according to the present embodiment, it is possible to concurrently form the opening 125 that extends in the thickness direction of the light-absorbing layer 120, and the pixel separator 123 that is provided on the light-absorbing layer 120 exposed in the opening 125. Accordingly, in the photoelectric conversion device 13, it is possible to reduce the number of steps of the manufacturing process. In addition, in the photoelectric conversion device 13, it is possible to sequentially form the opening 125 and the pixel separator 123, which makes it possible to form the pixel separator 123 having a concentration gradient of the impurity atom in the thickness direction of the light-absorbing layer 120.

### 4. APPLICATION EXAMPLES

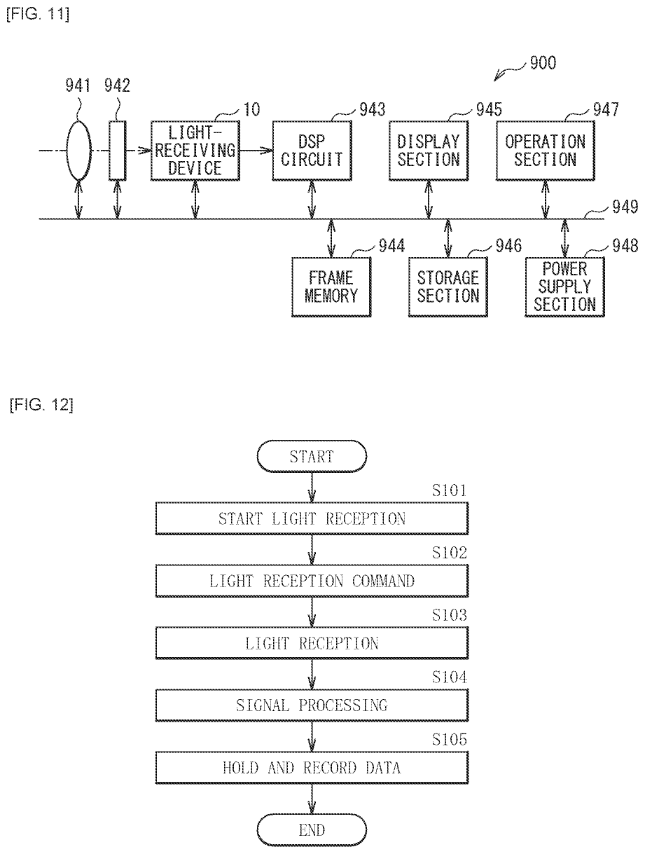

Description is given below of application examples of a light-receiving device 10 including a photoelectric conversion device according to an embodiment of the present disclosure with reference to FIGS. 11 to 16.

### (Application to Imaging System)

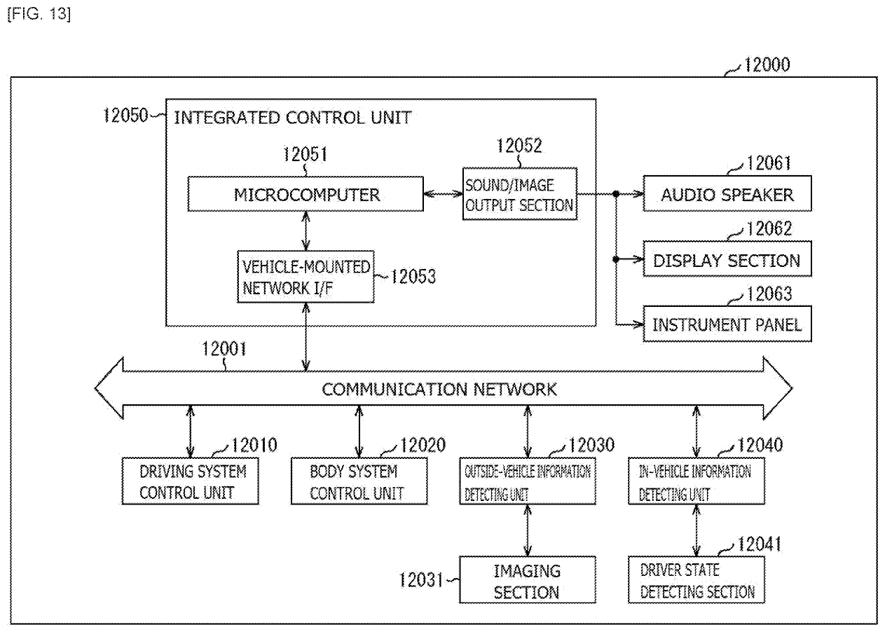

First, description is given of application of the light-receiving device 10 to an imaging system with reference to FIGS. 11 and 12. FIG. 11 is a block diagram illustrating a schematic configuration of an imaging system 900 including the light-receiving device 10. FIG. 12 is a flowchart diagram illustrating a flow of an imaging operation in the imaging system 900.

As illustrated in FIG. 11, examples of the imaging system 900 include an imaging device such as a digital still camera or a video camera, a portable terminal device having an imaging function such as a smartphone or a tablet-type terminal, an industrial machine or a transport machine having an imaging function, and the like.

The imaging system 900 includes, for example, a lens group 941, a shutter 942, the light-receiving device 10, a DSP circuit 943, a frame memory 944, a display section 945, a storage section 946, an operation section 947, and a power supply section 948. In the imaging system 900, the light-receiving device 10, the DSP circuit 943, the frame memory 944, the display section 945, the storage section 946, the operation section 947, and the power supply section 948 are coupled to one another via a bus line 949.

The light-receiving device 10 receives incident light having passed through the lens group 941 and the shutter 942, and outputs a sensor signal (that is, image data) corresponding to the received light. The DSP circuit 943 is a signal processing circuit that processes the image data outputted from the light-receiving device 10. The frame memory 944 temporarily holds the image data processed by the DSP circuit 943 in a frame unit. The display section 945 includes, for example, a panel-type display device such as a liquid crystal panel or an organic EL (Electro Luminescence) panel, and displays the image data processed by the DSP circuit 943. The storage section 946 includes a recording medium such as a semiconductor memory or a hard disk, and records the image data outputted from the light-receiving device 10 or the image data processed by the DSP circuit 943. The operation section 947 issues an operation command for various functions of the imaging system 900 on the basis of an operation by a user. The power supply section 948 includes various types of power supplies that supply power for operation of the light-receiving device 10, the DSP circuit 943, the frame memory 944, the display section 945, the storage section 946, and the operation section 947.

Next, description is given of an operation procedure in the imaging system 900.

As illustrated in FIG. 12, a user instructs start of light reception by operating the operation section 947 (S101). Thus, the operation section 947 transmits a light reception command to the light-receiving device 10 (S102). The light-receiving device 10 starts light reception by a predetermined method upon receiving the light reception command (S103).

Next, the light-receiving device 10 outputs image data corresponding to received light to the DSP circuit 943. The DSP circuit 943 performs predetermined signal processing (e.g., noise reduction processing, etc.) on the image data outputted from the light-receiving device 10 (S104). The DSP circuit 943 causes the frame memory 944 to hold the image data having been subjected to the predetermined signal processing. Thereafter, the frame memory 944 stores the image data in the storage section 946 (S105). In this manner, the operation of the imaging system 900 is performed.

### (Application to Mobile Body Control System)

The technology (the present technology) according to the present disclosure is applicable to various products. For example, the technology according to the present disclosure may be applied to a device to be mounted to a mobile body of any kind such as an automobile, an electric vehicle, a hybrid electric vehicle, a motorcycle, a bicycle, a personal mobility, an airplane, a drone, a vessel, or a robot.

FIG. 13 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 13, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 13, an audio speaker 12061, a display section 12062, and an instrument panel 12063 are illustrated as the output device. The display section 12062 may, for example, include at least one of an on-board display and a head-up display.

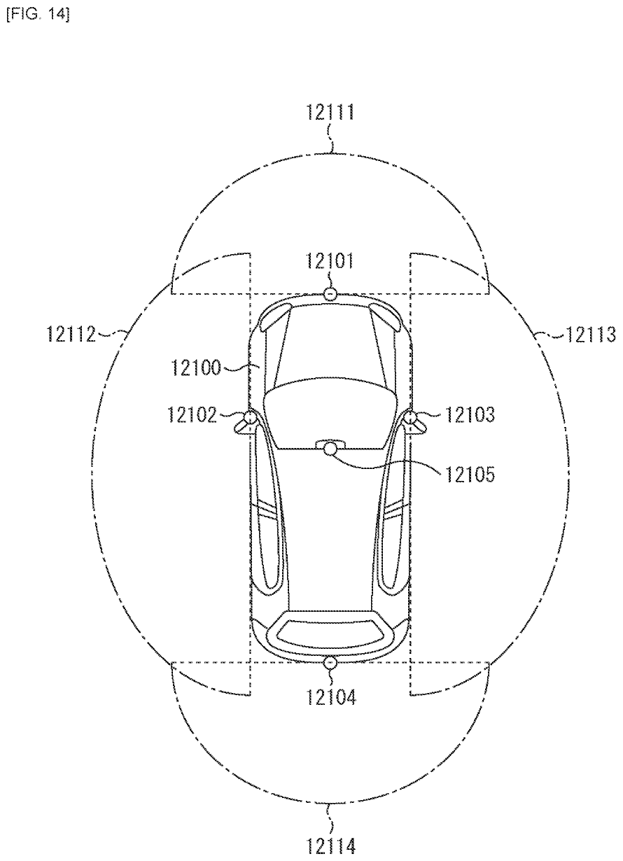

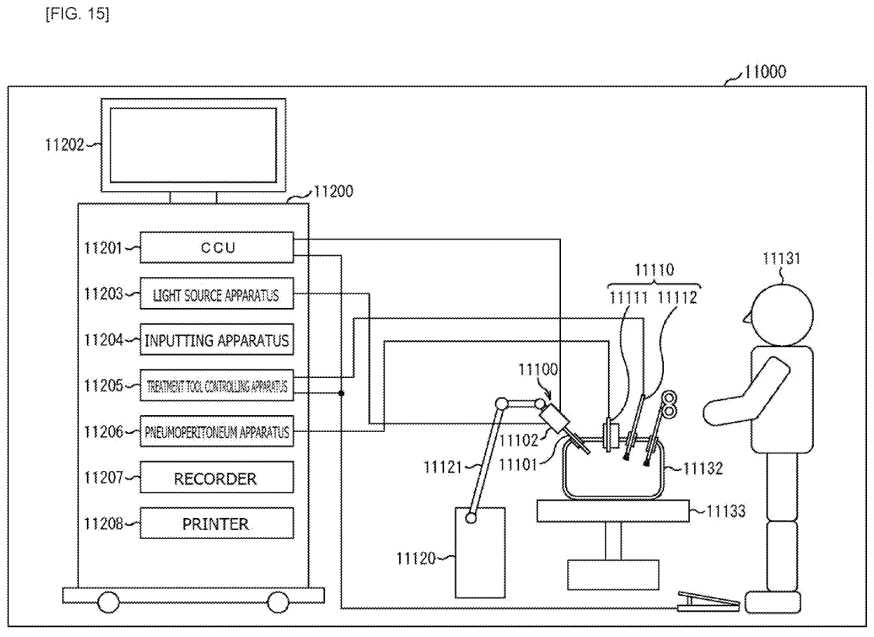

FIG. 14 is a diagram depicting an example of the installation position of the imaging section 12031.

In FIG. 14, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 14 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the mobile body control system, to which the technology according to the present disclosure may be applied. The technology according to the present disclosure may be applied to the imaging section 12031 among the configurations described above. According to the technology according to the present disclosure, it is possible to suppress crosstalk between pixels in the imaging section 12031, which makes it possible for the imaging section 12031 to acquire image data with higher image quality by infrared rays. Accordingly, for example, it is possible for the microcomputer 12051 or the like to control a vehicle with higher accuracy.

### (Application to Endoscopic Surgery System)

The technology (the present technology) according to the present disclosure is applicable to various products. For example, the technology according to the present disclosure may be applied to an endoscopic surgery system.

FIG. 15 is a view depicting an example of a schematic configuration of an endoscopic surgery system to which the technology according to an embodiment of the present disclosure (present technology) can be applied.

In FIG. 15, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

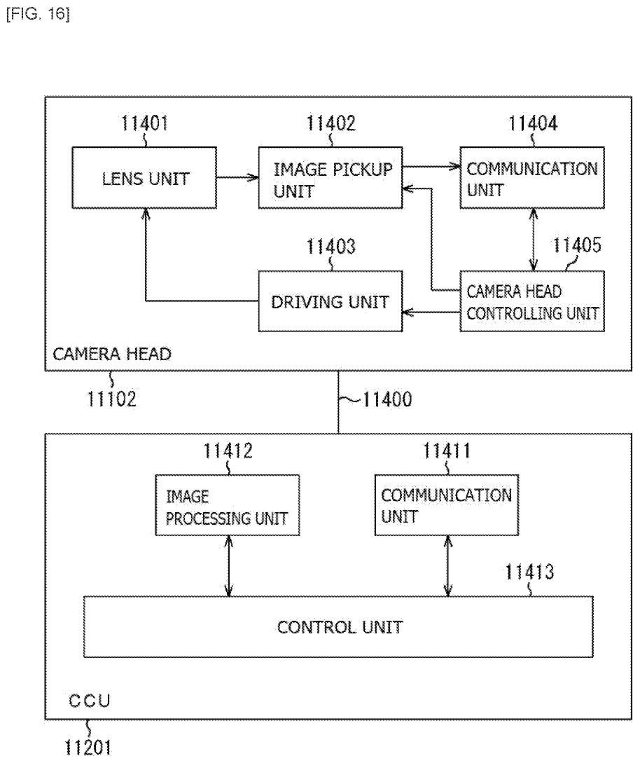

FIG. 16 is a block diagram depicting an example of a functional configuration of the camera head 11102 and the CCU 11201 depicted in FIG. 15.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like. The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given hereinabove of one example of the endoscopic surgery system, to which the technology according to the present disclosure may be applied. The technology according to the present disclosure may be suitably applied to the image pickup unit 11402 provided in the camera head 11102 of the endoscope 11100, among the configurations described above. According to the technology according to the present disclosure, it is possible for the image pickup unit 11402 to acquire a surgical region image with higher accuracy by infrared rays, which makes it possible to provide information with higher accuracy about the surgical region to a surgeon.

It is to be noted that the endoscopic surgery system has been described here as an example, but the technology according to the present disclosure may be additionally applied to, for example, a microscopic surgery system and the like.

The technology according to the present disclosure has been described above with reference to the first to third embodiments and the modification examples. However, the technology according to the present disclosure is not limited to the embodiments and the like described above, and may be modified in a variety of ways.

Further, not all of the components and operations described in the respective embodiments are necessary as the components and operations according to the present disclosure. For example, among components according to the respective embodiments, a component that is not described in an independent claim reciting the most generic concept of the present disclosure should be understood as an optional component.

Terms used throughout this specification and the appended claims should be construed as “non-limiting” terms. For example, the term “including” or “included” should be construed as “not limited to what is described as being included”. The term “having” should be construed as “not limited to what is described as being had”.

The terms used herein are used merely for the convenience of description and include terms that are not used to limit the configuration and the operation. For example, the terms such as “right”, “left”, “up”, and “down” only indicate directions in the drawings being referred to. In addition, the terms “inside” and “outside” only indicate a direction toward the center of a component of interest and a direction away from the center of a component of interest, respectively. The same applies to terms similar to these and to terms with the similar purpose.

It is to be noted that the technology according to the present disclosure may have the following configurations. According to the technology according to the present disclosure having the following configurations, a potential barrier by a pixel separator expands to a deeper region of a light-absorbing layer, thereby more firmly suppressing movement of signal electric charges between pixels. This makes it possible for the photoelectric conversion device to more firmly suppress crosstalk between the pixels. Effects attained by the technology according to the present disclosure are not necessarily limited to the effects described herein, but may include any of the effects described in the present disclosure.
(1)

A method of manufacturing a photoelectric conversion device including:

forming a photoelectric conversion structure in which a first semiconductor layer of a first electrical conductivity type is provided on a non-light-receiving surface, on side opposite to a light-receiving surface, of a light-absorbing layer including a compound semiconductor;

forming an opening by etching at least a portion of the photoelectric conversion structure, the opening that separates the photoelectric conversion structure for each pixel; and

forming a pixel separator of a second electrical conductivity type on the light-absorbing layer exposed in the opening, the pixel separator extending in a thickness direction of the light-absorbing layer.
(2)

The method of manufacturing the photoelectric conversion device according to (1), in which the photoelectric conversion structure includes the light-absorbing layer, the first semiconductor layer that is stacked on the non-light-receiving surface of the light-absorbing layer, and a second semiconductor layer of the second electrical conductivity type that is stacked on the light-receiving surface of the light-absorbing layer.
(3)

The method of manufacturing the photoelectric conversion device according to (2), in which the opening is formed by etching at least the first semiconductor layer of the photoelectric conversion structure.
(4)

The method of manufacturing the photoelectric conversion device according to (3), in which the pixel separator is formed by plasma doping of the light-absorbing layer with a source including an impurity of the second electrical conductivity type.
(5)

The method of manufacturing the photoelectric conversion device according to (4), in which the source gas includes a hydride gas of Si, As, P, Ge, or C.
(6)

The method of manufacturing the photoelectric conversion device according to any one of (3) to (5), in which

a surface of the light-absorbing layer exposed in the opening is flat, and the pixel separator is formed to extend to a region of the light-absorbing layer that is deeper on side of a middle portion of the opening than on side of an end of the opening.
(7)

The method of manufacturing the photoelectric conversion device according to any one of (3) to (6), in which

the opening is formed by etching the first semiconductor layer and the light-absorbing layer, and

the pixel separator is formed on the light-absorbing layer exposed on a side surface of the opening.
(8)

The method of manufacturing the photoelectric conversion device according to (7), in which the opening is formed to penetrate through the light-absorbing layer.
(9)

The method of manufacturing the photoelectric conversion device according to (3), in which the opening is formed by etching the first semiconductor layer and the light-absorbing layer, and

the pixel separator is formed by epitaxially growing a regrowth layer of the second electrical conductivity type on a side surface and a bottom surface of the opening.
(10)

The method of manufacturing the photoelectric conversion device according to (9), in which a corner at an upper end of the pixel separator formed on an inner side surface of the opening is chamfered.
(11)

The method of manufacturing the photoelectric conversion device according to (2), in which the opening is formed by etching the light-absorbing layer from side of the light-receiving surface, and

the pixel separator is formed by introducing a gas including an impurity atom of the second electrical conductivity type during the etching.
(12)

The method of manufacturing the photoelectric conversion device according to (11), in which the impurity atom includes an n-type impurity atom including C, Si, S, or Sn, or a p-type impurity atom including Zn, Mg, or Be.
(13)

The method of manufacturing the photoelectric conversion device according to (11) or (12), in which the pixel separator is formed to have a concentration gradient of the impurity atom in a thickness direction of the light-absorbing layer.
(14)

The method of manufacturing the photoelectric conversion device according to any one of (11) to (13), in which the opening is formed to penetrate through the light-absorbing layer.
(15)

The method of manufacturing the photoelectric conversion device according to any one of (11) to (14), in which the pixel separator is formed by alternately repeatedly performing the etching on the light-absorbing layer and doping of the light-absorbing layer with the impurity atom in a same chamber.
(16)

The method of manufacturing the photoelectric conversion device according to any one of (1) to (15), further including embedding an insulating material in the opening after forming the pixel separator.
(17)

The method of manufacturing the photoelectric conversion device according to (16), further including further embedding a metal material in the opening after embedding the insulating material in a region in which the pixel separator is exposed of the opening.
(18)

The method of manufacturing the photoelectric conversion device according to any one of (1) to (17), in which the compound semiconductor includes a III-V group compound semiconductor.
(19)

The method of manufacturing according to any one of (1) to (18), in which band gap energy of the first semiconductor layer is larger than band gap energy of the light-absorbing layer.
(20)

A photoelectric conversion device including:

a photoelectric conversion structure including a light-absorbing layer and a first semiconductor layer of a first electrical conductivity type, the light-absorbing layer including a compound semiconductor, and the first semiconductor layer provided on a non-light-receiving surface, on side opposite to a light-receiving surface, of the light-absorbing layer;

an opening that is provided to penetrate through at least a portion of the photoelectric conversion structure, and separates the photoelectric conversion structure for each pixel; and

a pixel separator of a second electrical conductivity type that is provided on the light-absorbing layer exposed in the opening, and extends in a thickness direction of the light-absorbing layer.

This application claims the benefit of Japanese Priority Patent Application JP2020-007097 filed with Japan Patent Office on Jan. 20, 2020, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A method of manufacturing a photoelectric conversion device comprising:
forming a photoelectric conversion structure in which a first semiconductor layer of a first electrical conductivity type is provided on a non-light-receiving surface, on side opposite to a light-receiving surface, of a light-absorbing layer including a compound semiconductor;
forming an opening by etching at least a portion of the photoelectric conversion structure, the opening that separates the photoelectric conversion structure for each pixel; and
forming a pixel separator of a second electrical conductivity type on the light-absorbing layer exposed in the opening, the pixel separator extending in a thickness direction of the light-absorbing layer.

2. The method of manufacturing the photoelectric conversion device according to claim 1, wherein the photoelectric conversion structure includes the light-absorbing layer, the first semiconductor layer that is stacked on the non-light-receiving surface of the light-absorbing layer, and a second semiconductor layer of the second electrical conductivity type that is stacked on the light-receiving surface of the light-absorbing layer.

3. The method of manufacturing the photoelectric conversion device according to claim 2, wherein the opening is formed by etching at least the first semiconductor layer of the photoelectric conversion structure.

4. The method of manufacturing the photoelectric conversion device according to claim 3, wherein the pixel separator is formed by plasma doping of the light-absorbing layer with a source including an impurity of the second electrical conductivity type.

5. The method of manufacturing the photoelectric conversion device according to claim 4, wherein the source gas includes a hydride gas of Si, As, P, Ge, or C.

6. The method of manufacturing the photoelectric conversion device according to claim 3, wherein
a surface of the light-absorbing layer exposed in the opening is flat, and
the pixel separator is formed to extend to a region of the light-absorbing layer that is deeper on side of a middle portion of the opening than on side of an end of the opening.

7. The method of manufacturing the photoelectric conversion device according to claim 3, wherein
the opening is formed by etching the first semiconductor layer and the light-absorbing layer, and
the pixel separator is formed on the light-absorbing layer exposed on a side surface of the opening.

8. The method of manufacturing the photoelectric conversion device according to claim 7, wherein the opening is formed to penetrate through the light-absorbing layer.

9. The method of manufacturing the photoelectric conversion device according to claim 3, wherein
the opening is formed by etching the first semiconductor layer and the light-absorbing layer, and
the pixel separator is formed by epitaxially growing a regrowth layer of the second electrical conductivity type on a side surface and a bottom surface of the opening.

10. The method of manufacturing the photoelectric conversion device according to claim 9, wherein a corner at an upper end of the pixel separator formed on an inner side surface of the opening is chamfered.

11. The method of manufacturing the photoelectric conversion device according to claim 2, wherein
the opening is formed by etching the light-absorbing layer from side of the light-receiving surface, and
the pixel separator is formed by introducing a gas including an impurity atom of the second electrical conductivity type during the etching.

12. The method of manufacturing the photoelectric conversion device according to claim 11, wherein the impurity atom comprises an n-type impurity atom including C, Si, S, or Sn, or a p-type impurity atom including Zn, Mg, or Be.

13. The method of manufacturing the photoelectric conversion device according to claim 11, wherein the pixel separator is formed to have a concentration gradient of the impurity atom in a thickness direction of the light-absorbing layer.

14. The method of manufacturing the photoelectric conversion device according to claim 11, wherein the opening is formed to penetrate through the light-absorbing layer.

15. The method of manufacturing the photoelectric conversion device according to claim 11, wherein the pixel separator is formed by alternately repeatedly performing the etching on the light-absorbing layer and doping of the light-absorbing layer with the impurity atom in a same chamber.

16. The method of manufacturing the photoelectric conversion device according to claim 1, further comprising embedding an insulating material in the opening after forming the pixel separator.

17. The method of manufacturing the photoelectric conversion device according to claim 16, further comprising further embedding a metal material in the opening after embedding the insulating material in a region in which the pixel separator is exposed of the opening.

18. The method of manufacturing the photoelectric conversion device according to claim 1, wherein the compound semiconductor comprises a III-V group compound semiconductor.

19. The method of manufacturing the photoelectric conversion device according to claim 1, wherein band gap energy of the first semiconductor layer is larger than band gap energy of the light-absorbing layer.

20. A photoelectric conversion device comprising:
a photoelectric conversion structure including a light-absorbing layer and a first semiconductor layer of a first electrical conductivity type, the light-absorbing layer including a compound semiconductor, and the first semiconductor layer provided on a non-light-receiving surface, on side opposite to a light-receiving surface, of the light-absorbing layer;
an opening that is provided to penetrate through at least a portion of the photoelectric conversion structure, and separates the photoelectric conversion structure for each pixel; and
a pixel separator of a second electrical conductivity type that is provided on the light-absorbing layer exposed in the opening, and extends in a thickness direction of the light-absorbing layer.
